(19) United States
(12) Patent Application Publication
(10) Pub. No.: US 2014/0026814 A1
(43) Pub. Date: Jan. 30, 2014

(54) VAPOR DEPOSITION APPARATUS AND METHOD OF MANUFACTURING ORGANIC LIGHT-EMITTING DISPLAY APPARATUS

(71) Applicants: Jae-Hyun KIM, Yongin-City (KR); Jin-Kwang KIM, Yongin-City (KR); Myung-Soo HUH, Yongin-City (KR)

(72) Inventors: Jae-Hyun KIM, Yongin-City (KR); Jin-Kwang KIM, Yongin-City (KR); Myung-Soo HUH, Yongin-City (KR)

(21) Appl. No.: 13/707,948

(22) Filed: Dec. 7, 2012

(30) Foreign Application Priority Data
Jul. 26, 2012 (KR) 10-2012-0081971

(51) Int. Cl. H01L 33/00

(52) U.S. Cl. CPC H01L 33/005
USPC 118/723 R; 118/715

(57) ABSTRACT

A vapor deposition apparatus includes at least one first region and at least one second region. A first blocking unit is arranged between a first exhausting unit and a first injecting unit and between the first exhausting unit and a first purging unit in the first region so as to avoid any common region between the first exhausting unit and the first injecting unit and to avoid any common region between the first exhausting unit and the first purging unit. The vapor deposition apparatus also includes another first blocking unit arranged between a second exhausting unit and a second injecting unit and between the second exhausting unit and a second purging unit in the second region so as to avoid any common region between the second exhausting unit and the second injecting unit and to avoid any common region between the second exhausting unit and the second purging unit.

### CROSS-REFERENCE TO RELATED PATENT APPLICATION

This application claims priority under 35 U.S.C. §119 to Korean Patent Application No. 10-2012-0081971, filed on Jul. 26, 2012, in the Korean Intellectual Property Office, the contents of which is incorporated herein in its entirety by reference.

### BACKGROUND

Semiconductor devices, display devices, and other electronic devices include a plurality of thin films. Various methods may be used to form the plurality of thin films, one of which is a vapor deposition method.

### SUMMARY

Embodiments may be realized by providing a vapor deposition apparatus for depositing a thin film on a substrate. The vapor deposition apparatus includes at least one first region having a first injecting unit for injecting a first raw material, a first purging unit for injecting a purge gas, and a first exhausting unit for performing a pumping operation and disposed between the first injecting unit and the first purging unit; at least one second region comprising a second injecting unit for injecting a second raw material, a second purging unit for injecting a purge gas, and a second exhausting unit for performing a pumping operation and disposed between the second injecting unit and the second purging unit; a first blocking unit A formed between the first exhausting unit and the first injecting unit and between the first exhausting unit and the first purging unit in the at least one first region so as not to allow the first exhausting unit and the first injecting unit to have a common region therebetween and not to allow the first exhausting unit and the first purging unit to have a common region therebetween; and a first blocking unit B formed between the second exhausting unit and the second injecting unit and between the second exhausting unit and the second purging unit in the at least one second region so as not to allow the second exhausting unit and the second injecting unit to have a common region therebetween and not to allow the second exhausting unit and the second purging unit to have a common region therebetween.

The vapor deposition apparatus may further include a second blocking unit A that is formed adjacent to a side surface of the first injecting unit which is in an opposite direction with respect to the first exhausting unit and that is formed between the first injecting unit and a gas injecting unit of another second region adjacent to the first injecting unit, and the first blocking unit A may extend to correspond to at least the second blocking unit A.

The vapor deposition apparatus may further include a second blocking unit A that is formed adjacent to a side surface of the first injecting unit which is in an opposite direction with respect to the first exhausting unit and that is formed between the first injecting unit and a gas injecting unit of another second region adjacent to the first injecting unit, and a bottom surface of the first blocking unit A and a bottom surface of the second blocking unit A may be in parallel, coplanar, with each other.

The vapor deposition apparatus may further include a second blocking unit B that is formed adjacent to a side surface of the second injecting unit which is in an opposite direction with respect to the second exhausting unit and that is formed between the second injecting unit and a gas injecting unit of another first region adjacent to the second injecting unit, and the first blocking unit B may extend to correspond to at least the second blocking unit B.

The vapor deposition apparatus may further include a second blocking unit B that is formed adjacent to a side surface of the second injecting unit which is in an opposite direction with respect to the second exhausting unit and that is formed between the second injecting unit and a gas injecting unit of another first region adjacent to the second injecting unit, and a bottom surface of the first blocking unit B and a bottom surface of the second blocking unit B may be in parallel, e.g., coplanar, with each other.

The vapor deposition apparatus may further include a third blocking unit A that is formed adjacent to a side surface of the first purging unit which is in an opposite direction with respect to the first exhausting unit and that defines the first purging unit, and the first blocking unit A may extend to correspond to at least the third blocking unit A.

The vapor deposition apparatus may further include a third blocking unit A that is formed adjacent to a side surface of the first purging unit which is in an opposite direction with respect to the first exhausting unit and that defines the first purging unit, and a bottom surface of the first blocking unit A and a bottom surface of the third blocking unit A may be in parallel, e.g., coplanar, with each other.

The vapor deposition apparatus may further include a third blocking unit B that is formed adjacent to a side surface of the second purging unit which is in an opposite direction with respect to the second exhausting unit and that defines the second purging unit, and the first blocking unit B may extend to correspond to at least the third blocking unit B.

The vapor deposition apparatus may further include a third blocking unit B that is formed adjacent to a side surface of the second purging unit which is in an opposite direction with respect to the second exhausting unit and that defines the second purging unit, and a bottom surface of the first blocking unit B and a bottom surface of the third blocking unit B may be in parallel, e.g., coplanar, with each other.

The vapor deposition apparatus may further include a first curtain unit that is disposed between a first purging unit of the at least one first region and a second injecting unit of the at least one second region. The first purging unit may be disposed closer to the first exhausting unit than the first curtain unit. A gas pressure applied to the first purging unit may be greater than a gas pressure applied to the first curtain unit. A width of the first purging unit may be less than a width of the first curtain unit. A height of the first purging unit may be less than a height of the first curtain unit. A supply unit for supplying a purge gas to the first purging unit may be connected with another supply unit for supplying a curtain gas to the first curtain unit.

The vapor deposition apparatus may further include a second curtain unit that is disposed between a second purging unit of the at least one second region and a first injecting unit of the at least one first region. The second purging unit may be disposed closer to the second exhausting unit than the second curtain unit. A gas pressure applied to the second purging unit may be greater than a gas pressure applied to the second curtain unit. A width of the second purging unit may be less than a width of the second curtain unit. A height of the second purging unit may be less than a height of the second curtain unit.

A supply unit for supplying a purge gas to the second purging unit may be connected with another supply unit for supplying a curtain gas to the second curtain unit. A vapor deposition procedure may be performed while the substrate and the vapor deposition apparatus relatively move with respect to each other. The second raw material in a radical form may be injected into the substrate.

A second injecting unit of the at least one second region may include a plasma generator; a corresponding surface corresponding to the plasma generator; a plasma generation space formed between the plasma generator and the corresponding surface; a plurality of slits arrayed in one direction and formed to pass the second raw material in a radical form, wherein the second raw material is formed in the plasma generation space; and an injection region via which the second raw material that passed through the plurality of slits are injected into the substrate.

The plurality of slits may further have slits that are formed in another direction crossing the one direction. Slits in a center from among the plurality of slits may be smaller than slits in a side from among the plurality of slits.

The vapor deposition apparatus may include a plurality of second regions, and slits arranged in one of the plurality of second regions may deviate from slits arranged in another one of the plurality of second regions. Side surfaces of each of the plurality of slits may be curved.

The plasma generator may rotate in one direction. The vapor deposition apparatus may include a plurality of second regions, and a plasma generator arranged in one of the plurality of second regions, and a plasma generator arranged in another one of the plurality of second regions may rotate in different directions.

The vapor deposition apparatus may include a plurality of first regions and a plurality of second regions, and the plurality of first regions and the plurality of second regions may be alternately disposed, respectively.

Embodiments may also be realized by providing a method of manufacturing an organic light-emitting display apparatus, the method includes an operation of forming a thin film on a substrate by using a vapor deposition apparatus, wherein the thin film at least includes a first electrode, an intermediate layer comprising an organic emission layer (organic EML), a second electrode, and an encapsulation layer, and the vapor deposition apparatus includes at least one first region comprising a first injecting unit for injecting a first raw material, a first purging unit for injecting a purge gas, and a first exhausting unit for performing a pumping operation and disposed between the first injecting unit and the first purging unit; at least one second region comprising a second injecting unit for injecting a second raw material, a second purging unit for injecting a purge gas, and a second exhausting unit for performing a pumping operation and disposed between the second injecting unit and the second purging unit; a first blocking unit A formed between the first exhausting unit and the first injecting unit and between the first exhausting unit and the first purging unit in the at least one first region so as not to allow the first exhausting unit and the first injecting unit to have a common region therebetween and not to allow the first exhausting unit and the first purging unit to have a common region therebetween; and a first blocking unit B formed between the second exhausting unit and the second injecting unit and between the second exhausting unit and the second purging unit in the at least one second region so as not to allow the second exhausting unit and the second injecting unit to have a common region therebetween and not to allow the second exhausting unit and the second purging unit to have a common region therebetween, and the operation of forming the thin film may be performed while the substrate and the vapor deposition apparatus relatively move with respect to each other.

The operation of forming the thin film may include an operation of forming the encapsulation layer disposed on the second electrode. The operation of forming the thin film may include an operation of forming an insulating layer. The operation of forming the thin film may include an operation of forming a conductive layer.

### BRIEF DESCRIPTION OF THE DRAWINGS

Features will become more apparent to those of ordinary skill in the art by describing in detail exemplary embodiments thereof with reference to the attached drawings in which:

FIG. 1 is a cross-sectional view of a vapor deposition apparatus according to an exemplary embodiment;

FIG. 2 is a magnified view of first regions 110A in FIG. 1;

FIG. 3 is a magnified view of a portion S in FIG. 1;

FIG. 4A is a cross-sectional view of slits, taken along line IV-IV of FIG. 3;

FIGS. 4B through 4D illustrate other examples of the slits of FIG. 1;

FIG. 5 is a cross-sectional view of a vapor deposition apparatus according to an exemplary embodiment;

FIG. 6 is a magnified view of a portion P in FIG. 5;

FIG. 7 is a cross-sectional view of a vapor deposition apparatus according to an exemplary embodiment;

FIG. 8 is a cross-sectional view of a vapor deposition apparatus according to an exemplary embodiment;

FIG. 9 is a cross-sectional view of an organic light-emitting display apparatus manufactured by an organic light-emitting display apparatus manufacturing method, according to an exemplary embodiment; and

FIG. 10 is a magnified view of a portion F in FIG. 9.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the figures, the dimensions of layers and regions may be exaggerated for clarity of illustration. Like reference numerals refer to like elements throughout.

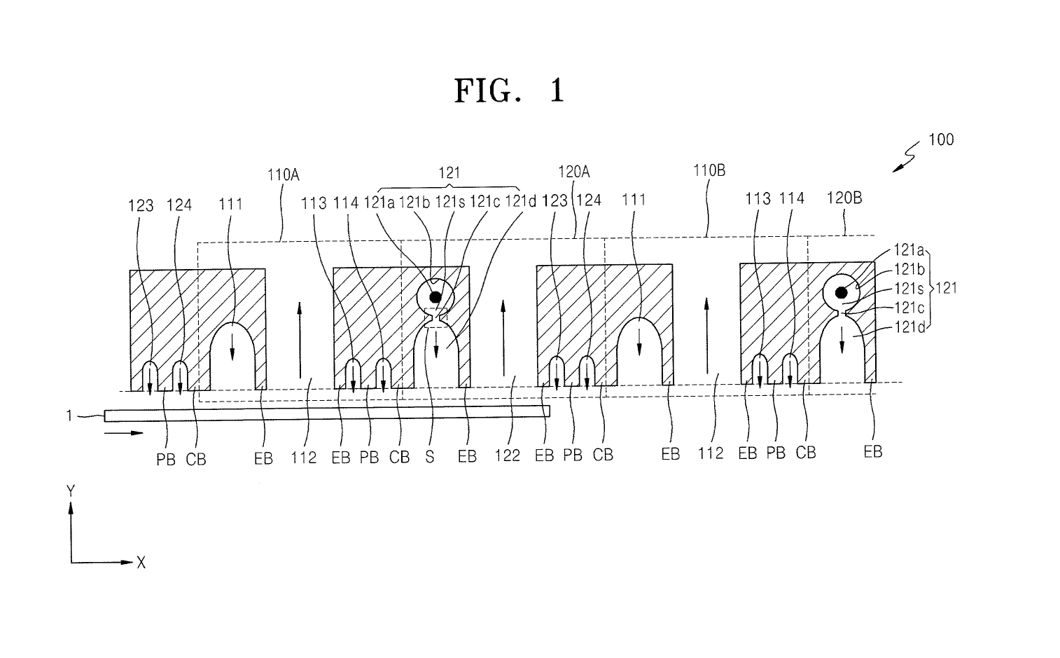

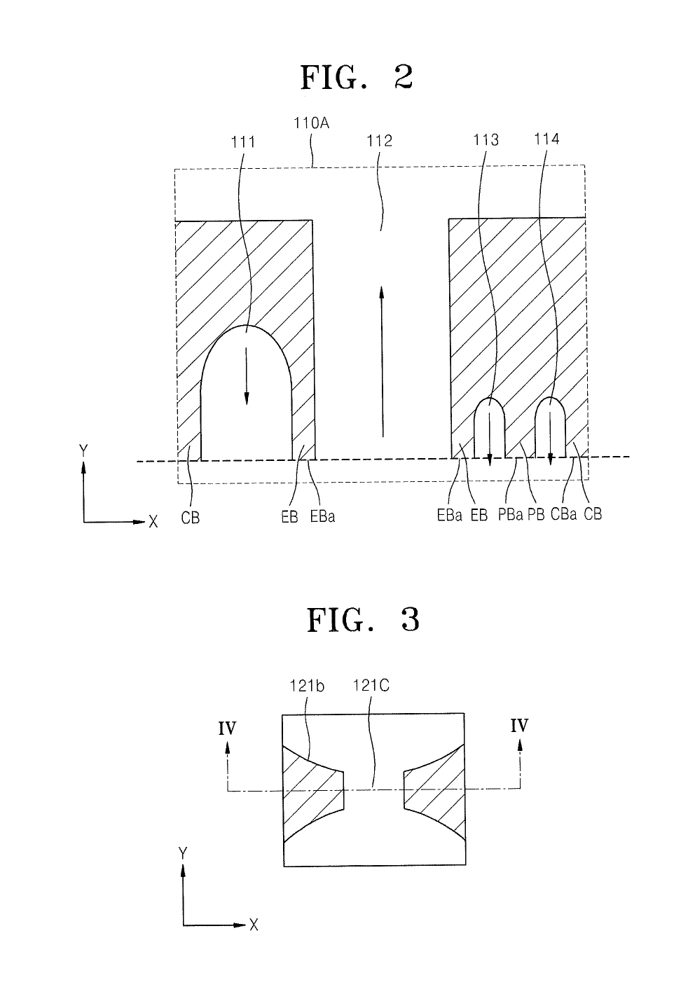

FIG. 1 is a cross-sectional view of a vapor deposition apparatus 100 according to an exemplary embodiment. FIG. 2 is a magnified view of the first regions 110A in FIG. 1. FIG. 3 is a magnified view of a portion S in FIG. 1.

Referring to FIGS. 1 through 3, the vapor deposition apparatus 100 includes one or more first regions 110A and 110B, and one or more second regions 120A and 120B. A substrate 1 is deposed below the vapor deposition apparatus 100. A desired deposition layer is formed on the substrate 1 by using the vapor deposition apparatus 100. A structure of the vapor deposition apparatus 100 shown in FIGS. 1 through 3 is for convenience of description and thus the vapor deposition apparatus 100 may include first regions in various numbers and second regions in various numbers.

The second region 120A is disposed to be adjacent to the first region 110A, and the first region 110B is disposed to be adjacent to the second region 120A. The second region 120B is disposed to be adjacent to the first region 110B. That is, the first regions 110A and 110B and the second regions 120A and 120B are alternately disposed.

The first region 110A and the second region 120A will now be described in detail.

The first region 110A includes a first injecting unit 111, a first exhausting unit 112, a first purging unit 113, and a first curtain unit 114.

The first injecting unit 111 injects a first raw material for deposition. In more detail, the first injecting unit 111 injects the first raw material in a gaseous phase to the substrate 1.

The first purging unit 113 injects a purge gas to the substrate 1. The first purging unit 113 injects a gas such as an argon gas or a nitrogen gas, which does not affect the deposition, to the substrate 1.

The first exhausting unit 112 pumps in an arrow direction shown in FIG. 1. The first exhausting unit 112 is disposed between the first injecting unit 111 and the first purging unit 113.

After the first raw material is injected from the first injecting unit 111 to the substrate 1, the purge gas is injected to the substrate 1 via the first purging unit 113 and then the first exhausting unit 112 performs a pumping operation, so that one layer containing the first raw material is formed on the substrate 1 (detailed descriptions thereof will be provided later).

The first curtain unit 114 is formed to be adjacent to the second region 120A. The first curtain unit 114 injects a curtain gas. The curtain gas may be an inert gas that does not affect a deposition procedure.

In the present embodiment, the deposition procedure is performed while the substrate 1 and the vapor deposition apparatus 100 relatively move with respect to each other. In this regard, because the first curtain unit 114 is formed to be adjacent to the second region 120A, the first curtain unit 114 may reduce the possibility of and/or prevent a material, which is generated in or is inserted into the first region 110A, from intruding into the second region 120A, and may reduce the possibility of and/or prevent a material, which is generated in or is inserted into the second region 120A from intruding into the first region 110A, when the deposition procedure is performed.

In order to divide the first exhausting unit 112 and the first injecting unit 111 that is adjacent to the first exhausting unit 112, and to divide the first exhausting unit 112 and the first purging unit 113 that is adjacent to the first exhausting unit 112, first blocking units A EB are formed, respectively. That is, the first exhausting unit 112 and the first injecting unit 111 do not have a common region therebetween, i.e., so the first exhausting unit 112 is entirely excluded from a region that consists entirely of the first injecting unit 111. Further, the first exhausting unit 112 and the first purging unit 113 do not have a common region therebetween.

In order to divide the first injecting unit 111 and another gas injecting unit such as a curtain unit 124 that is disposed on the left side of the first region 110A and that is adjacent to the first injecting unit 111, a second blocking unit A CB is formed between the first injecting unit 111 and the curtain unit 124. Also, in order to divide the first purging unit 113 and the first curtain unit 114 that is adjacent to the first purging unit 113, a third blocking unit A PB is formed between the first purging unit 113 and the first curtain unit 114.

The first blocking unit A EB has a lower portion that corresponds to at least the second blocking unit A CB and the third blocking unit A PB. That is, the first blocking unit A EB extends to correspond to at least the second blocking unit A CB and the third blocking unit A PB.

For example, as illustrated in FIG. 2, a bottom surface EBa of the first blocking unit A EB may be in parallel with a bottom surface CBa of the second blocking unit A CB and a bottom surface PBa of the third blocking unit A PB. In other words, the bottom surface EBa and the bottom surface CBa may be coplanar, e.g., arranged along a same horizontal line.

The second region 120A includes a second injecting unit 121, a second exhausting unit 122, a second purging unit 123, and a second curtain unit 124.

The second injecting unit 121 injects a second raw material for deposition. In more detail, the second injecting unit 121 includes a plasma generator 121a. A corresponding surface 121b corresponds to the plasma generator 121a. A plasma generation space 121s is arranged between the plasma generator 121a and the corresponding surface 121b. A type of the plasma generator 121a may vary. For example, the plasma generator 121a may be an electrode, and in this case, the corresponding surface 121b may also function as an electrode corresponding to the plasma generator 121a.

Plasma is generated due to a reaction between the plasma generator 121a and the corresponding surface 121b in the plasma generation space 121s, the second raw material in a radical form is injected into an injection region 121d via a slit 121c, and then is delivered to the substrate 1 via the injection region 121d. In this manner, the second injecting unit 121 injects the second raw material in the radical form to the substrate 1.

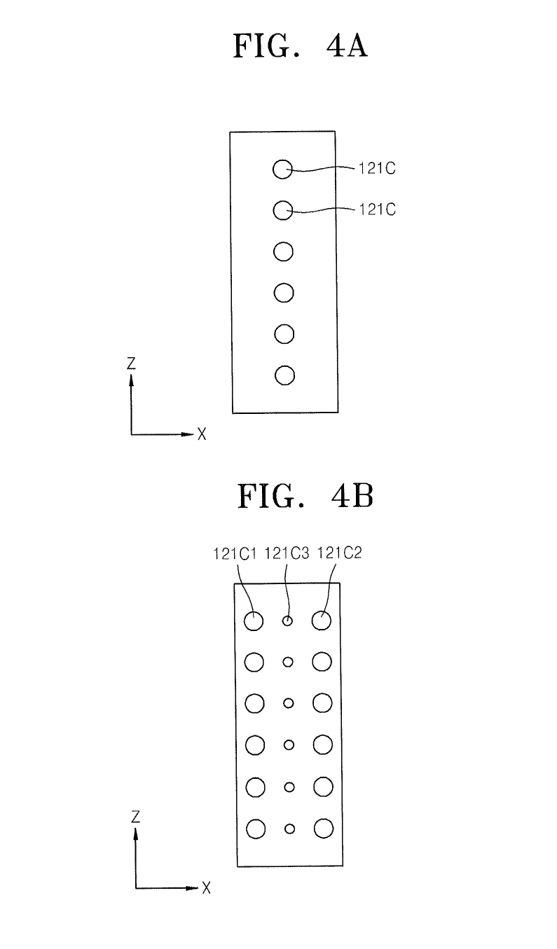

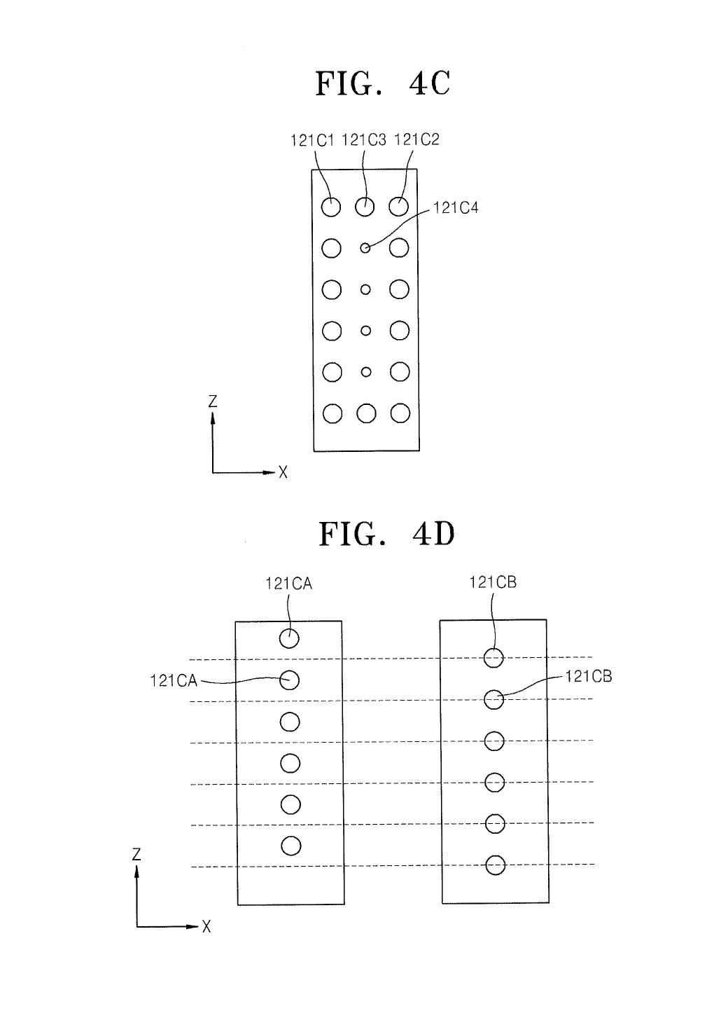

FIG. 4A is a cross-sectional view of the slits 121c, taken along line IV-IV of FIG. 3. Referring to FIG. 4A, a plurality of the slits 121c are formed at regular intervals in one direction. The second raw material in the radical form which is generated in the plasma generation space 121s via the plurality of the slits 121c is not locally concentrated on the injection region 121d but may be uniformly supplied to injection region 121d.

A form of the slit 121c may vary. That is, as illustrated in FIGS. 4B through 4D, the slits 121c with various forms may be formed.

Referring to FIG. 4B, a plurality of the slits 121c are formed in two directions. That is, not one slit 121c, as shown in FIGS. 1 and 4A, but three of the slits 121c such as slits 121c1, 121c2, and 121c3 are formed in an X-axis direction, so that the second raw material is efficiently injected to the substrate 1, and in particular, an injection uniformity of the second raw material is improved. In particular, referring to FIG. 4B, the slits 121c1 are formed in one side, the slits 121c2 are formed in the other side, and the slits 121c3 are formed in a center. The slit 121c3 in the center has a size that is smaller than a size of each of the slit 121c1 in one side and the slit 121c2 in the other side. Thus, a high pressure is applied to the slit 121c3 in the center, and a low pressure is applied to the slit 121c1 in one side and the slit 121c2 in the other side, so that, when the second raw material is injected into the injection region 121d, the second raw material is symmetrically injected about the slit 121c3 in the center. Because the substrate 1 moves in the X-axis direction, the second raw material is uniformly injected to an entire region of the substrate 1.

Referring to FIG. 4C, a plurality of the slits 121c that are slits 121c1, 121c2, and 121c3 are formed at side ends. Also, slits 121c4 are formed in a center between the side ends. A size of the slits 121c4 in the center is smaller than a size of the slits 121c1, 121c2, and 121c3 at the side ends.

FIG. 4D illustrates slits 121CA in the second region 120A of FIG. 1 and slits 121CB in the second region 120B of FIG. 1. As illustrated in FIG. 4D, the slits 121CA in the second region 120A, and the slits 121 CB in the second region 120B deviate with respect to each other, and by doing so, when the second raw material is injected to the substrate 1, the injection is uniformly performed.

Although not illustrated, the present embodiment may include various slits. That is, the present embodiment may include the slits with shapes and sizes that vary.

The second purging unit 123 injects a purge gas to the substrate 1. The second purging unit 123 injects a gas such as an argon gas or a nitrogen gas, which does not affect the deposition, to the substrate 1.

The second exhausting unit 122 pumps in an arrow direction shown in FIG. 1. The second exhausting unit 122 is disposed between the second injecting unit 121 and the second purging unit 123.

After the second raw material is injected from the second injecting unit 121 to the substrate 1, the purge gas is injected to the substrate 1 via the second purging unit 123 and then the second exhausting unit 122 performs a pumping operation, so that one layer containing the first raw material and the second raw material is formed on the substrate 1 (detailed descriptions thereof will be provided later).

The second curtain unit 124 is formed to be adjacent to the first region 110B. The second curtain unit 124 injects a curtain gas. The curtain gas may be an inert gas that does not affect the deposition procedure.

In the present embodiment, the deposition procedure is performed while the substrate 1 and the vapor deposition apparatus 100 relatively move with respect to each other. In this regard, because the second curtain unit 124 is formed to be adjacent to the first region 110B, the second curtain unit 124 may reduce the possibility of and/or prevent a material, which is generated in or is inserted into the second region 120A, from intruding into the first region 110B, and may reduce the possibility of and/or prevent a material, which is generated in or is inserted into the first region 110B from intruding into the second region 120A, when the deposition procedure is performed.

In order to divide the second exhausting unit 122 and the second injecting unit 121 that is adjacent to the second exhausting unit 122, and to divide the second exhausting unit 122 and the second purging unit 123 that is adjacent to the second exhausting unit 122, first blocking units B EB are formed, respectively. That is, the second exhausting unit 122 and the second injecting unit 121 do not have a common region therebetween, and the second exhausting unit 122 and the second purging unit 123 do not have a common region therebetween.

In order to divide the second injecting unit 121 and another gas injecting unit such as the first curtain unit 114 of the first region 110A, a second blocking unit B CB is formed between the second injecting unit 121 and the first curtain unit 114. Also, in order to divide the second purging unit 123 and the second curtain unit 124 that is adjacent to the second purging unit 123, a third blocking unit B PB is formed between the second purging unit 123 and the second curtain unit 124.

The first blocking unit B EB has a lower portion that corresponds to at least the second blocking unit B CB and the third blocking unit B PB. That is, a bottom surface of the first blocking unit B EB is in parallel, e.g., coplanar, with a bottom surface of the second blocking unit B CB and a bottom surface of the third blocking unit B PB.

The first region 110B and the second region 120B that are adjacent to each other are the same as the first region 110A and the second region 120A, and thus detailed descriptions thereof are omitted here.

Hereinafter, a deposition procedure using the vapor deposition apparatus 100 will be briefly described.

The substrate 1 is moved toward the vapor deposition apparatus 100. That is, the substrate 1 is moved in the X-axis direction of FIG. 1. To do so, the substrate 1 may be mounted on a stage (not shown) and then the substrate 1 on the stage may be moved by using a driving unit (not shown). Alternatively, instead of the substrate 1, the vapor deposition apparatus 100 may be moved in the X-axis direction.

The first raw material is injected toward the substrate 1 via the first injecting unit 111 in the first region 110A. For example, the first raw material may be a gas containing aluminum (Al) atoms such as trimethylaluminum (TMA). Due to the injection, an adsorbent layer containing aluminum (Al) is formed on a top surface of the substrate 1. In more detail, a chemical adsorbent layer and a physical adsorbent layer are formed on the top surface of the substrate 1.

Of the adsorbent layers formed on the top surface of the substrate 1, the physical adsorbent layer, which has weak combination between molecules, may be separated from the substrate 1 due to the purge gas injected by the first purging unit 113. Here, the physical adsorbent layer is effectively removed from the substrate 1 by a pumping operation of the first exhausting unit 112, so that a purity of a deposition layer to be finally formed on the substrate 1 is improved. In this regard, when the first exhausting unit 112 performs the pumping operation, the directivity of the first raw material injected by the first injecting unit 111 or the directivity of the purge gas injected by the first purging unit 113 is not affected. That is, the first blocking unit A EB that is formed to divide the first exhausting unit 112 and the first purging unit 113 has the lower portion that corresponds to the second blocking unit A CB and the third blocking unit A PB. That is, a bottom surface of the first blocking unit A EB is in parallel, e.g., coplanar, with a bottom surface of the second blocking unit A CB and a bottom surface of the third blocking unit A PB, so that the first blocking unit A EB may reduce the possibility of and/or prevent the pumping operation by the first exhausting unit 112 from undesirably affecting the first injecting unit 111 and the first purging unit 113.

Afterward, the substrate 1 is moved and then the second raw material is injected via the second injecting unit 121 of the second region 120A. The first region 110A and the second region 120A are effectively divided due to the first curtain unit 114 of the first region 110A, so that it may be possible to prevent undesired substances from intruding into each process of the deposition procedure.

The second injecting unit 121 injects the second raw material in the radical form, which is generated in the plasma generation space 121s. For example, the second raw material includes an oxygen radical. The oxygen radical is generated by injecting H₂O, O₂, N₂O, or the like into the plasma generation space 121s. The second raw material reacts with the chemical adsorbent layer or metathesizes a portion of the chemical adsorbent layer that is already adsorbed to the substrate 1 and that is formed of the first raw material, so that, finally, a desired deposition layer, e.g., an AlₓO_{y} layer is formed. Here, a surplus of the second raw material is formed as the physical adsorbent layer and thus remains.

When the purge gas is injected by the second purging unit 123, the physical adsorbent layer remaining on the top surface of the substrate 1 may be separated. Here, the physical adsorbent layer is effectively removed from the substrate 1 by a pumping operation of the second purging unit 123, so that a purity of a deposition layer to be finally formed on the substrate 1 is improved. In this regard, when the second exhausting unit 122 performs the pumping operation, the directivity of the second raw material injected by the second injecting unit 121 or the directivity of the purge gas injected by the second purging unit 123 is not affected. That is, the first blocking unit B EB that is formed to divide the second exhausting unit 122 and the second purging unit 123 has a lower portion that corresponds to the second blocking unit B CB and the third blocking unit B PB. That is, the bottom surface of the first blocking unit B EB is in parallel, e.g., coplanoar, with the bottom surface of the second blocking unit B CB and the bottom surface of the third blocking unit B PB, so that the first blocking unit B EB may reduce the possibility of and/or prevent the pumping operation by the second exhausting unit 122 from undesirably affecting the second injecting unit 121 and the second purging unit 123.

While the substrate 1 passes through the first region 110A and the second region 120A, a desired single atomic layer is formed on the substrate 1.

In the present embodiment, it may be possible to prevent a pumping effect by the first and second exhausting units 112 and 122 from undesirably affecting the first and second injecting units 111 and 121, and the first and second purging units 113 and 123. By doing so, a deposition layer having a high purity is formed.

Also, the second raw material is effectively and uniformly injected via the plurality of slits 121c, so that the uniformity of the deposition layer is increased

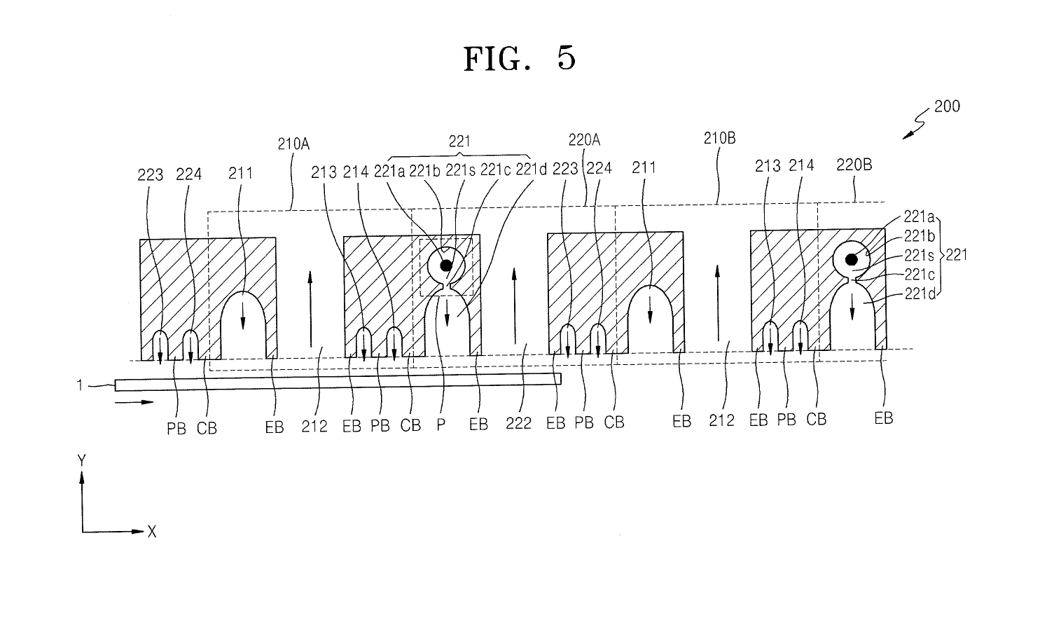

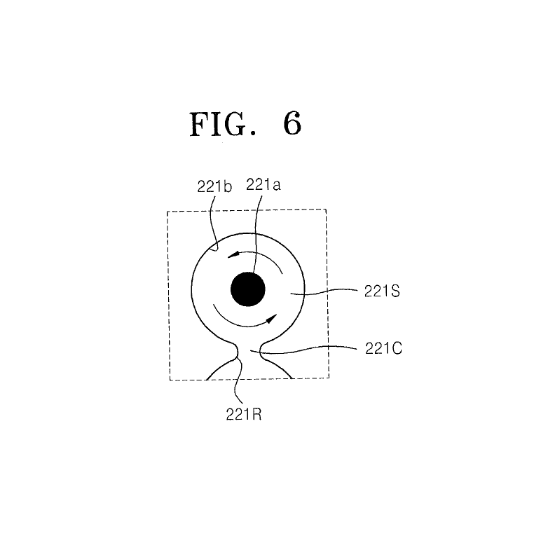

FIG. 5 is a cross-sectional view of a vapor deposition apparatus 200 according to another exemplary embodiment. FIG. 6 is a magnified view of P in FIG. 5. For convenience of description, the present embodiment will be described with respect to features different from those of the previous embodiment.

Referring to FIGS. 5 and 6, the vapor deposition apparatus 200 includes one or more first regions 210A and 210B, and one or more second regions 220A and 220B. A substrate 1 is deposed below the vapor deposition apparatus 200. A desired deposition layer is formed on the substrate 1 by using the vapor deposition apparatus 200.

The second region 220A is disposed to be adjacent to the first region 210A, and the first region 210B is disposed to be adjacent to the second region 220A. The second region 220B is disposed to be adjacent to the first region 210B.

The first region 210A and the second region 220A will now be described in detail.

The first region 210A includes a first injecting unit 211, a first exhausting unit 212, a first purging unit 213, and a first curtain unit 214.

The first injecting unit 211 injects a first raw material for deposition. In more detail, the first injecting unit 211 injects the first raw material in a gas state to the substrate 1.

The first purging unit 213 injects a purge gas to the substrate 1. The first purging unit 213 injects a gas such as an argon gas or a nitrogen gas, which does not affect the deposition, to the substrate 1.

The first exhausting unit 212 pumps in an arrow direction shown in FIG. 5. The first exhausting unit 212 is disposed between the first injecting unit 211 and the first purging unit 213.

After the first raw material is injected from the first injecting unit 211 to the substrate 1, the purge gas is injected to the substrate 1 via the first purging unit 213 and then the first exhausting unit 212 performs a pumping operation, so that one layer containing the first raw material is formed on the substrate 1.

The first curtain unit 214 is formed to be adjacent to the second region 220A. The first curtain unit 214 injects a curtain gas. The curtain gas may be an inert gas that does not affect a deposition procedure.

In the present embodiment, the deposition procedure is performed while the substrate 1 and the vapor deposition apparatus 200 relatively move with respect to each other. In this regard, because the first curtain unit 214 is formed to be adjacent to the second region 220A, the first curtain unit 214 may reduce the possibility of and/or prevent a material, which is generated in or is inserted into the first region 210A, from intruding into the second region 220A, and may reduce the possibility of and/or prevent a material of the second region 220A from intruding into the first region 210A, when the deposition procedure is performed.

In order to divide the first exhausting unit 212 and the first injecting unit 211 that is adjacent to the first exhausting unit 212, and to divide the first exhausting unit 212 and the first purging unit 213 that is adjacent to the first exhausting unit 212, first blocking units A EB are formed, respectively. That is, the first exhausting unit 212 and the first injecting unit 211 do not have a common region therebetween, and the first exhausting unit 212 and the first purging unit 213 do not have a common region therebetween.

In order to divide the first injecting unit 211 and another gas injecting unit such as a curtain unit 224 that is disposed on the left side of the first region 210A and that is adjacent to the first injecting unit 211, a second blocking unit A CB is formed. Also, in order to divide the first purging unit 213 and the first curtain unit 214 that is adjacent to the first purging unit 213, a third blocking unit A PB is formed between the first purging unit 213 and the first curtain unit 214.

The first blocking unit A EB has a lower portion that corresponds to at least the second blocking unit A CB and the third blocking unit A PB. That is, as illustrated in FIG. 5, a bottom surface of the first blocking unit A EB is in parallel, e.g., coplanar, with a bottom surface of the second blocking unit A CB and a bottom surface of the third blocking unit A PB.

The second region 220A includes a second injecting unit 221, a second exhausting unit 222, a second purging unit 223, and a second curtain unit 224.

The second injecting unit 221 injects a second raw material for deposition. In more detail, the second injecting unit 221 includes a plasma generator 221a. A corresponding surface 221b corresponds to the plasma generator 221a. A plasma generation space 221s is arranged between the plasma generator 221a and the corresponding surface 221b. A type of the plasma generator 221a may vary. For example, the plasma generator 221a may be an electrode, and in this case, the corresponding surface 221b may also function as an electrode corresponding to the plasma generator 221a.

Plasma is generated due to a reaction between the plasma generator 221a and the corresponding surface 221b in the plasma generation space 221s, the second raw material in a radical form is injected into an injection region 221d via a slit 221c, and then is delivered to the substrate 1 via the injection region 221d. In this manner, the second injecting unit 221 injects the second raw material in the radical form to the substrate 1.

In particular, as illustrated in FIG. 6, the plasma generator 221a rotates in one direction. Due to the rotation, the plasma may be uniformly distributed in the plasma generation space 221s, and arc generation may be prevented. Here, the plasma generator 221a of the second region 220A, and the plasma generator 221a of the second region 220B that is adjacent to the second region 220A rotate in opposite directions. By doing so, the second raw material may be uniformly injected to an entire region of the substrate 1.

Because the arc generation irregularly occurs at upper and lower corners of side surfaces forming the slit 221c, the uniformity of the second raw material may deteriorate. In this regard, according to the present embodiment, side surfaces 221R that form the slit 221c are curved as illustrated in FIG. 6, so that the arc generation may be effectively prevented.

The second purging unit 223 injects a purge gas to the substrate 1. The second purging unit 223 injects a gas such as an argon gas or a nitrogen gas, which does not affect the deposition, to the substrate 1.

The second exhausting unit 222 pumps in an arrow direction shown in FIG. 5. The second exhausting unit 222 is disposed between the second injecting unit 221 and the second purging unit 223.

After the second raw material is injected from the second injecting unit 221 to the substrate 1, the purge gas is injected to the substrate 1 via the second purging unit 223 and then the second exhausting unit 222 performs a pumping operation, so that one layer containing the first raw material and the second raw material is formed on the substrate 1.

The second curtain unit 224 is formed to be adjacent to the first region 210B. The second curtain unit 224 injects a curtain gas. The curtain gas may be an inert gas that does not affect the deposition procedure.

In the present embodiment, the deposition procedure is performed while the substrate 1 and the vapor deposition apparatus 200 relatively move with respect to each other. In this regard, because the second curtain unit 224 is formed to be adjacent to the first region 210B, the second curtain unit 224 may reduce the possibility of and/or prevent a material, which is generated in or is inserted into the second region 220A, from intruding into the first region 210B, and may reduce the possibility of and/or prevent a material of the first region 210B from intruding into the second region 220A, when the deposition procedure is performed.

In order to divide the second exhausting unit 222 and the second injecting unit 221 that is adjacent to the second exhausting unit 222, and to divide the second exhausting unit 222 and the second purging unit 223 that is adjacent to the second exhausting unit 222, first blocking units B EB are formed, respectively. That is, the second exhausting unit 222 and the second injecting unit 221 do not have a common region therebetween, and the second exhausting unit 222 and the second purging unit 223 do not have a common region therebetween.

In order to divide the second injecting unit 221 and another gas injecting unit such as the first curtain unit 214 of the first region 210A, a second blocking unit B CB is formed between the second injecting unit 221 and the first curtain unit 214. Also, in order to divide the second purging unit 223 and the second curtain unit 224 that is adjacent to the second purging unit 223, a third blocking unit B PB is formed between the second purging unit 223 and the second curtain unit 224.

The first blocking unit B EB has a lower portion that corresponds to at least the second blocking unit B CB and the third blocking unit B PB. That is, a bottom surface of the first blocking unit B EB is in parallel, e.g., coplanar, with a bottom surface of the second blocking unit B CB and a bottom surface of the third blocking unit B PB.

The first region 210B and the second region 220B that are adjacent to each other are the same as the first region 210A and the second region 220A, and thus detailed descriptions thereof are omitted here.

A deposition procedure using the vapor deposition apparatus 200 is the same as that in the previous embodiment and thus detailed descriptions thereof are omitted here.

In the present embodiment, it may be possible to prevent a pumping effect by the first and second exhausting units 212 and 222 from undesirably affecting the first and second injecting units 211 and 221, and the first and second purging units 213 and 223. By doing so, the deposition layer having a high purity may be formed.

Also, the uniformity of the plasma is increased due to the rotation of the plasma generator 221a. That is, it may be possible to prevent irregular distribution of the plasma in the plasma generation space 221s, or to prevent the arc generation from affecting the substrate 1.

Also, because the second raw material is effectively and uniformly injected via the plurality of slits 121c, the uniformity of the deposition layer is increased, and because the side surfaces 221R of the slit 221c are curved, the arc generation during the plasma generation may be prevented, so that the second raw material having a high purity is injected into the substrate 1 and thus a characteristic of the deposition layer formed on the substrate 1 is improved.

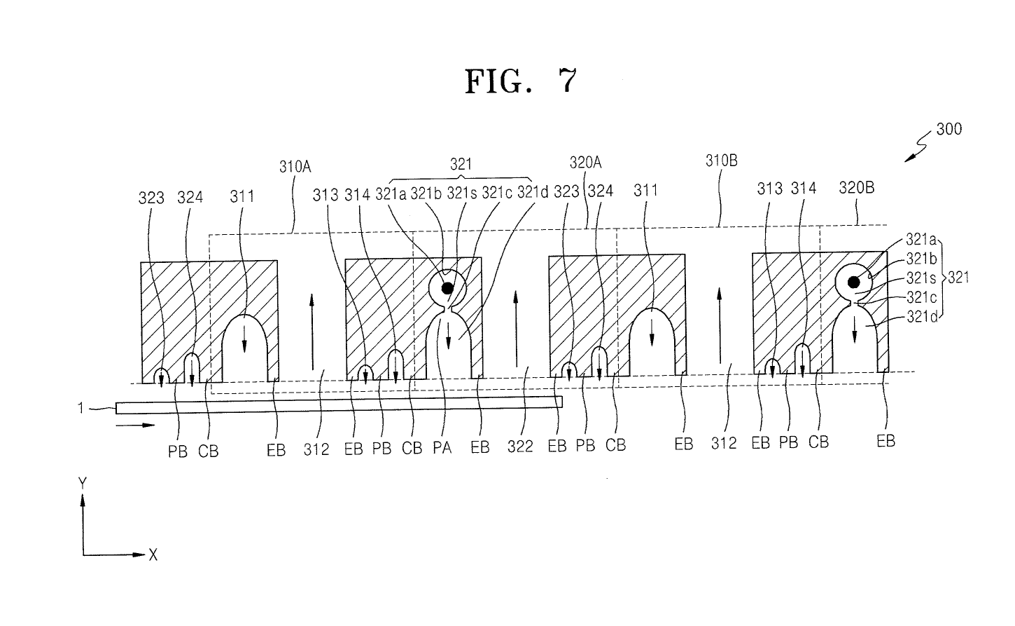

FIG. 7 is a cross-sectional view of a vapor deposition apparatus 300 according to another exemplary embodiment. For convenience of description, the present embodiment will be described with respect to features different from those of the previous embodiments.

Referring to FIG. 7, the vapor deposition apparatus 300 includes one or more first regions 310A and 310B, and one or more second regions 320A and 320B. A substrate 1 is deposed below the vapor deposition apparatus 300. A desired deposition layer is formed on the substrate 1 by using the vapor deposition apparatus 300.

The second region 320A is disposed to be adjacent to the first region 310A, and the first region 310B is disposed to be adjacent to the second region 320A. The second region 320B is disposed to be adjacent to the first region 310B.

The first region 310A and the second region 320A will now be described in detail.

The first region 310A includes a first injecting unit 311, a first exhausting unit 312, a first purging unit 313, and a first curtain unit 314.

The first injecting unit 311 injects a first raw material for deposition. In more detail, the first injecting unit 311 injects the first raw material in a gas state to the substrate 1.

The first purging unit 313 injects a purge gas to the substrate 1. The first purging unit 313 injects a gas such as an argon gas or a nitrogen gas, which does not affect the deposition, to the substrate 1.

The first exhausting unit 312 pumps in an arrow direction shown in FIG. 7. The first exhausting unit 312 is disposed between the first injecting unit 311 and the first purging unit 313.

After the first raw material is injected from the first injecting unit 311 to the substrate 1, the purge gas is injected to the substrate 1 via the first purging unit 313 and then the first exhausting unit 312 performs a pumping operation, so that one layer containing the first raw material is formed on the substrate 1.

The first curtain unit 314 is formed to be adjacent to the second region 320A. The first curtain unit 314 injects a curtain gas. The curtain gas may be an inert gas that does not affect a deposition procedure.

In the present embodiment, the deposition procedure is performed while the substrate 1 and the vapor deposition apparatus 300 relatively move with respect to each other. In this regard, because the first curtain unit 314 is formed to be adjacent to the second region 320A, the first curtain unit 314 may reduce the possibility of and/or prevent a material, which is generated in or is inserted into the first region 310A, from intruding into the second region 320A, and may reduce the possibility of and/or prevent a material of the second region 320A from intruding into the first region 310A, when the deposition procedure is performed.

The first purging unit 313 has a space smaller than a space of the first curtain unit 314. In more detail, a height of the first purging unit 313 is less than a height of the first curtain unit 314. By doing so, a gas pressure applied to the first purging unit 313 is greater than a gas pressure applied to the first curtain unit 314. As illustrated in FIG. 7, the first purging unit 313 is disposed closer to the first exhausting unit 312 than the first curtain unit 314. That is, in a pumping operation by the first exhausting unit 312, the first purging unit 313 is further affected by the exhausting unit 312, compared to the first curtain unit 314, such that a purge gas injection characteristic of the first purging unit 313 may deteriorate. In particular, when a supply unit (not shown) for supplying the purge gas to the first purging unit 313 is connected with a supply unit (not shown) for supplying a first curtain gas to the first curtain unit 314, it is difficult to separately control pressures of gases supplied to the first purging unit 313 and the first curtain unit 314. Thus, the purge gas injection characteristic of the first purging unit 313 that is further affected by the pumping operation of the exhausting unit 312 may deteriorate.

In the present embodiment, the first purging unit 313 has the height less than the height of the first curtain unit 314, so that the gas pressure applied to the first purging unit 313 is greater than the gas pressure applied to the first curtain unit 314, and thus a characteristic of the first purging unit 313 is effectively improved.

In order to divide the first exhausting unit 312 and the first injecting unit 311 that is adjacent to the first exhausting unit 312, and to divide the first exhausting unit 312 and the first purging unit 313 that is adjacent to the first exhausting unit 312, first blocking units A EB are formed, respectively. That is, the first exhausting unit 312 and the first injecting unit 311 do not have a common region therebetween, and the first exhausting unit 312 and the first purging unit 313 do not have a common region therebetween.

In order to divide the first injecting unit 311 and another gas injecting unit such as a curtain unit 324 that is disposed on the left side of the first region 310A and that is adjacent to the first injecting unit 311, a second blocking unit A CB is formed. Also, in order to divide the first purging unit 313 and the first curtain unit 314 that is adjacent to the first purging unit 313, a third blocking unit A PB is formed between the first purging unit 313 and the first curtain unit 314.

The first blocking unit A EB has a lower portion that corresponds to at least the second blocking unit A CB and the third blocking unit A PB. That is, as illustrated in FIG. 7, a bottom surface of the first blocking unit A EB is in parallel, e.g., coplanar, with a bottom surface of the second blocking unit A CB and a bottom surface of the third blocking unit A PB.

The second region 320A includes a second injecting unit 321, a second exhausting unit 322, a second purging unit 323, and a second curtain unit 324.

The second injecting unit 321 injects a second raw material for deposition. In more detail, the second injecting unit 321 includes a plasma generator 321a. A corresponding surface 321b corresponds to the plasma generator 321a. A plasma generation space 321s is arranged between the plasma generator 321a and the corresponding surface 321b. A type of the plasma generator 321a may vary. For example, the plasma generator 321a may be an electrode, and in this case, the corresponding surface 321b may also function as an electrode corresponding to the plasma generator 321a.

Plasma is generated due to a reaction between the plasma generator 321a and the corresponding surface 321b in the plasma generation space 321s, the second raw material in a radical form is injected into an injection region 321d via a slit 321c, and then is delivered to the substrate 1 via the injection region 321d. In this manner, the second injecting unit 321 injects the second raw material in the radical form to the substrate 1.

The second purging unit 323 injects a purge gas to the substrate 1. The second purging unit 323 injects a gas such as an argon gas or a nitrogen gas, which does not affect the deposition, to the substrate 1.

The second exhausting unit 322 pumps in an arrow direction shown in FIG. 7. The second exhausting unit 322 is disposed between the second injecting unit 321 and the second purging unit 323.

After the second raw material is injected from the second injecting unit 321 to the substrate 1, the purge gas is injected to the substrate 1 via the second purging unit 323 and then the second exhausting unit 322 performs a pumping operation, so that one layer containing the first raw material and the second raw material is formed on the substrate 1.

The second curtain unit 324 is formed to be adjacent to the first region 310B. The second curtain unit 324 injects a curtain gas. The curtain gas may be an inert gas that does not affect the deposition procedure.

In the present embodiment, the deposition procedure is performed while the substrate 1 and the vapor deposition apparatus 300 relatively move with respect to each other. In this regard, because the second curtain unit 324 is formed to be adjacent to the first region 310B, the second curtain unit 324 may reduce the possibility of and/or prevent a material, which is generated in or is inserted into the second region 320A, from intruding into the first region 310B, and may reduce the possibility of and/or prevent a material of the first region 310B from intruding into the second region 320A, when the deposition procedure is performed.

The second purging unit 323 has a space smaller than a space of the second curtain unit 324. In more detail, a height of the second purging unit 323 is less than a height of the second curtain unit 324. By doing so, a gas pressure applied to the second purging unit 323 is greater than a gas pressure applied to the second curtain unit 324. As illustrated in FIG. 7, the second purging unit 323 is disposed closer to the second exhausting unit 322 than the second curtain unit 324. That is, in a pumping operation by the second exhausting unit 322, the second purging unit 323 is further affected by the exhausting unit 322, compared to the second curtain unit 324, such that a purge gas injection characteristic of the second purging unit 323 may deteriorate.

In the present embodiment, the second purging unit 323 has the height less than the height of the second curtain unit 324, so that the gas pressure applied to the second purging unit 323 is greater than the gas pressure applied to the second curtain unit 324, and thus a characteristic of the second purging unit 323 is effectively improved.

In order to divide the second exhausting unit 322 and the second injecting unit 321 that is adjacent to the second exhausting unit 322, and to divide the second exhausting unit 322 and the second purging unit 323 that is adjacent to the second exhausting unit 322, first blocking units B EB are formed, respectively. That is, the second exhausting unit 322 and the second injecting unit 321 do not have a common region therebetween, and the second exhausting unit 322 and the second purging unit 323 do not have a common region therebetween.

In order to divide the second injecting unit 321 and another gas injecting unit such as the first curtain unit 314 of the first region 310A, a second blocking unit B CB is formed between the second injecting unit 321 and the first curtain unit 314. Also, in order to divide the second purging unit 323 and the second curtain unit 324 that is adjacent to the second purging unit 323, a third blocking unit B PB is formed between the second purging unit 323 and the second curtain unit 324.

The first blocking unit B EB has a lower portion that corresponds to at least the second blocking unit B CB and the third blocking unit B PB. That is, a bottom surface of the first blocking unit B EB is in parallel, e.g., coplanar, with a bottom surface of the second blocking unit B CB and a bottom surface of the third blocking unit B PB.

The first region 310B and the second region 320B that are adjacent to each other are the same as the first region 310A and the second region 320A, and thus detailed descriptions thereof are omitted here.

A deposition procedure using the vapor deposition apparatus 300 is the same as that in the previous embodiments and thus detailed descriptions thereof are omitted here.

In the present embodiment, it may be possible to prevent a pumping effect by the first and second exhausting units 312 and 322 from undesirably affecting the first and second injecting units 311 and 321, and the first and second purging units 313 and 323. By doing so, the deposition layer having a high purity may be formed.

Also, heights of the first and second purging units 313 and 323, which are disposed close to the first and second exhausting units 312 and 322, are less than heights of the first and second curtain units 314 and 324, so that a gas pressure applied to the first and second purging units 313 and 323 is greater than a gas pressure applied to the first and second curtain units 314 and 324, and thus, a purge characteristic of the first and second purging units 313 and 323 is improved. By improving the purge characteristic, it may be possible to prevent foreign substances from intruding into each process of the deposition procedure, so that the deposition layer having a high purity may be formed on the substrate 1.

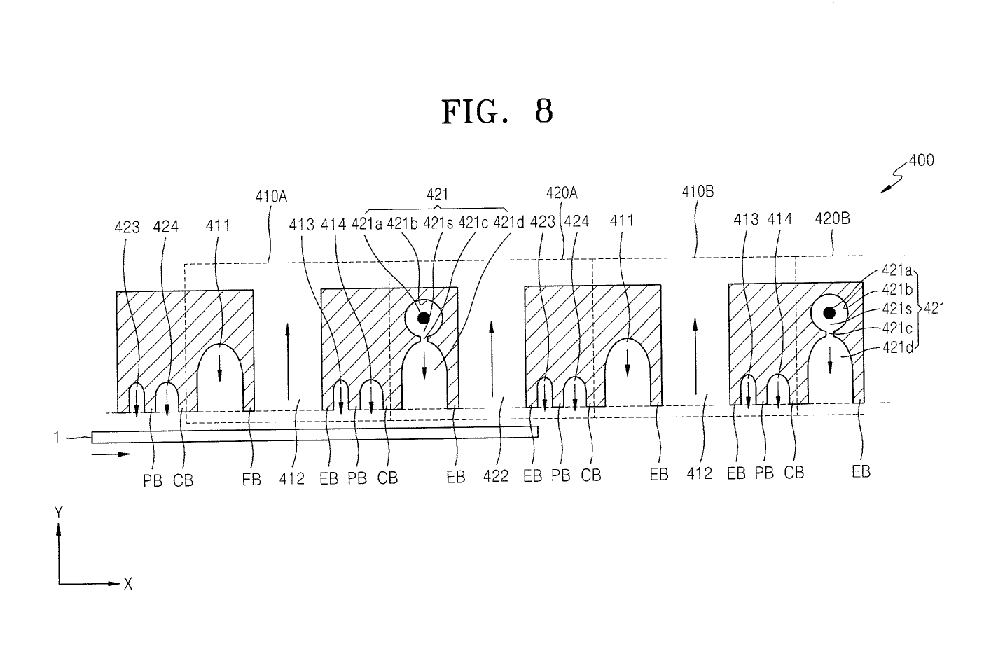

FIG. 8 is a cross-sectional view of a vapor deposition apparatus 400 according to another exemplary embodiment. For convenience of description, the present embodiment will be described with respect to features different from those of the previous embodiments.

Referring to FIG. 8, the vapor deposition apparatus 400 includes one or more first regions 410A and 410B, and one or more second regions 420A and 420B. A substrate 1 is deposed below the vapor deposition apparatus 400. A desired deposition layer is formed on the substrate 1 by using the vapor deposition apparatus 400.

The second region 420A is disposed to be adjacent to the first region 410A, and the first region 410B is disposed to be adjacent to the second region 420A. The second region 420B is disposed to be adjacent to the first region 410B.

The first region 410A and the second region 420A will now be described in detail.

The first region 410A includes a first injecting unit 411, a first exhausting unit 412, a first purging unit 413, and a first curtain unit 414.

The first injecting unit 411 injects a first raw material for deposition. In more detail, the first injecting unit 411 injects the first raw material in a gas state to the substrate 1.

The first purging unit 413 injects a purge gas to the substrate 1. The first purging unit 413 injects a gas such as an argon gas or a nitrogen gas, which does not affect the deposition, to the substrate 1.

The first exhausting unit 412 pumps in an arrow direction shown in FIG. 8. The first exhausting unit 412 is disposed between the first injecting unit 411 and the first purging unit 413.

After the first raw material is injected from the first injecting unit 411 to the substrate 1, the purge gas is injected to the substrate 1 via the first purging unit 413, and then the first exhausting unit 412 performs a pumping operation, so that one layer containing the first raw material is formed on the substrate 1.

The first curtain unit 414 is formed to be adjacent to the second region 420A. The first curtain unit 414 injects a curtain gas. The curtain gas may be an inert gas that does not affect a deposition procedure.

In the present embodiment, the deposition procedure is performed while the substrate 1 and the vapor deposition apparatus 400 relatively move with respect to each other. In this regard, because the first curtain unit 414 is formed to be adjacent to the second region 420A, the first curtain unit 414 may reduce the possibility of and/or prevent a material, which is generated in or is inserted into the first region 410A, from intruding into the second region 420A, and may reduce the possibility of and/or prevent a material of the second region 420A from intruding into the first region 410A, when the deposition procedure is performed.

The first purging unit 413 has a space smaller than a space of the first curtain unit 414. In more detail, a width of the first purging unit 413 is less than a width of the first curtain unit 414. By doing so, a gas pressure applied to the first purging unit 413 is greater than a gas pressure applied to the first curtain unit 414. As illustrated in FIG. 8, the first purging unit 413 is disposed closer to the first exhausting unit 412 than the first curtain unit 414. That is, in a pumping operation by the first exhausting unit 412, the first purging unit 413 is further affected by the exhausting unit 412, compared to the first curtain unit 414, such that a purge gas injection characteristic of the first purging unit 413 may deteriorate. In the present embodiment, the first purging unit 413 has the width less than the width of the first curtain unit 414, so that the gas pressure applied to the first purging unit 413 is greater than the gas pressure applied to the first curtain unit 414, and thus a characteristic of the first purging unit 413 is effectively improved.

In order to divide the first exhausting unit 412 and the first injecting unit 411 that is adjacent to the first exhausting unit 412, and to divide the first exhausting unit 412 and the first purging unit 413 that is adjacent to the first exhausting unit 412, first blocking units A EB are formed, respectively. That is, the first exhausting unit 412 and the first injecting unit 411 do not have a common region therebetween, and the first exhausting unit 412 and the first purging unit 413 do not have a common region therebetween.

In order to divide the first injecting unit 411 and another gas injecting unit such as a curtain unit 424 that is disposed on the left side of the first region 410A and that is adjacent to the first injecting unit 411, a second blocking unit A CB is formed. Also, in order to divide the first purging unit 413 and the first curtain unit 414 that is adjacent to the first purging unit 413, a third blocking unit A PB is formed between the first purging unit 413 and the first curtain unit 414.

The first blocking unit A EB has a lower portion that corresponds to at least the second blocking unit A CB and the third blocking unit A PB. That is, as illustrated in FIG. 8, a bottom surface of the first blocking unit A EB is in parallel, e.g., coplanar, with a bottom surface of the second blocking unit A CB and a bottom surface of the third blocking unit A PB.

The second region 420A includes a second injecting unit 421, a second exhausting unit 422, a second purging unit 423, and a second curtain unit 424.

The second injecting unit 421 injects a second raw material for deposition. In more detail, the second injecting unit 421 includes a plasma generator 421a. A corresponding surface 421b corresponds to the plasma generator 421a. A plasma generation space 421s is arranged between the plasma generator 421a and the corresponding surface 421b. A type of the plasma generator 421a may vary. For example, the plasma generator 421a may be an electrode, and in this case, the corresponding surface 421b may also function as an electrode corresponding to the plasma generator 421a.

Plasma is generated due to a reaction between the plasma generator 421a and the corresponding surface 421b in the plasma generation space 421s, the second raw material in a radical form is injected into an injection region 421d via a slit 421c, and then is delivered to the substrate 1 via the injection region 421d. In this manner, the second injecting unit 421 injects the second raw material in the radical form to the substrate 1.

The second purging unit 423 injects a purge gas to the substrate 1. The second purging unit 423 injects a gas such as an argon gas or a nitrogen gas, which does not affect the deposition, to the substrate 1.

The second exhausting unit 422 pumps in an arrow direction shown in FIG. 8. The second exhausting unit 422 is disposed between the second injecting unit 421 and the second purging unit 423.

After the second raw material is injected from the second injecting unit 421 to the substrate 1, the purge gas is injected to the substrate I via the second purging unit 423, and then the second exhausting unit 422 performs a pumping operation, so that one layer containing the first raw material and the second raw material is formed on the substrate 1.

The second curtain unit 424 is formed to be adjacent to the first region 410B. The second curtain unit 424 injects a curtain gas. The curtain gas may be an inert gas that does not affect the deposition procedure.

In the present embodiment, the deposition procedure is performed while the substrate 1 and the vapor deposition apparatus 300 relatively move with respect to each other. In this regard, because the second curtain unit 424 is formed to be adjacent to the first region 410B, the second curtain unit 424 may reduce the possibility of and/or prevent a material, which is generated in or is inserted into the second region 420A, from intruding into the first region 410B, and may reduce the possibility of and/or prevent a material of the first region 410B from intruding into the second region 420A, when the deposition procedure is performed.

The second purging unit 423 has a space smaller than a space of the second curtain unit 424. In more detail, a width of the second purging unit 423 is less than a width of the second curtain unit 424. By doing so, a gas pressure applied to the second purging unit 423 is greater than a gas pressure applied to the second curtain unit 424. As illustrated in FIG. 8, the second purging unit 423 is disposed closer to the second exhausting unit 422 than the second curtain unit 424. That is, in a pumping operation by the second exhausting unit 422, the second purging unit 423 is further affected by the exhausting unit 422, compared to the second curtain unit 424, such that a purge gas injection characteristic of the second purging unit 423 may deteriorate.

In the present embodiment, the width of the second purging unit 423 is less than the width of the second curtain unit 424, so that the gas pressure applied to the second purging unit 423 is greater than the gas pressure applied to the second curtain unit 424, and thus a characteristic of the second purging unit 423 is effectively improved.

In order to divide the second exhausting unit 422 and the second injecting unit 421 that is adjacent to the second exhausting unit 422, and to divide the second exhausting unit 422 and the second purging unit 423 that is adjacent to the second exhausting unit 422, first blocking units B EB are formed, respectively. That is, the second exhausting unit 422 and the second injecting unit 421 do not have a common region therebetween, and the second exhausting unit 422 and the second purging unit 423 do not have a common region therebetween.

In order to divide the second injecting unit 421 and another gas injecting unit such as the first curtain unit 414 of the first region 410A, a second blocking unit B CB is formed between the second injecting unit 421 and the first curtain unit 414. Also, in order to divide the second purging unit 423 and the second curtain unit 424 that is adjacent to the second purging unit 423, a third blocking unit B PB is formed between the second purging unit 423 and the second curtain unit 424.

The first blocking unit B EB has a lower portion that corresponds to at least the second blocking unit B CB and the third blocking unit B PB. That is, a bottom surface of the first blocking unit B EB is in parallel, e.g., coplanar, with a bottom surface of the second blocking unit B CB and a bottom surface of the third blocking unit B PB.

The first region 410B and the second region 420B that are adjacent to each other are the same as the first region 410A and the second region 420A, and thus detailed descriptions thereof are omitted here.

A deposition procedure using the vapor deposition apparatus 400 is the same as that in the previous embodiments and thus detailed descriptions thereof are omitted here.

In the present embodiment, it may be possible to prevent a pumping effect by the first and second exhausting units 412 and 422 from undesirably affecting the first and second injecting units 411 and 421, and the first and second purging units 413 and 423. By doing so, the deposition layer having a high purity may be formed.

Also, widths of the first and second purging units 413 and 423, which are disposed close to the first and second exhausting units 412 and 422, are less than widths of the first and second curtain units 414 and 424, so that a gas pressure applied to the first and second purging units 413 and 423 is greater than a gas pressure applied to the first and second curtain units 414 and 424, and thus, a purge characteristic of the first and second purging units 413 and 423 is improved. By improving the purge characteristic, it may be possible to prevent foreign substances from intruding into each process of the deposition procedure, so that the deposition layer having a high purity may be formed on the substrate 1.

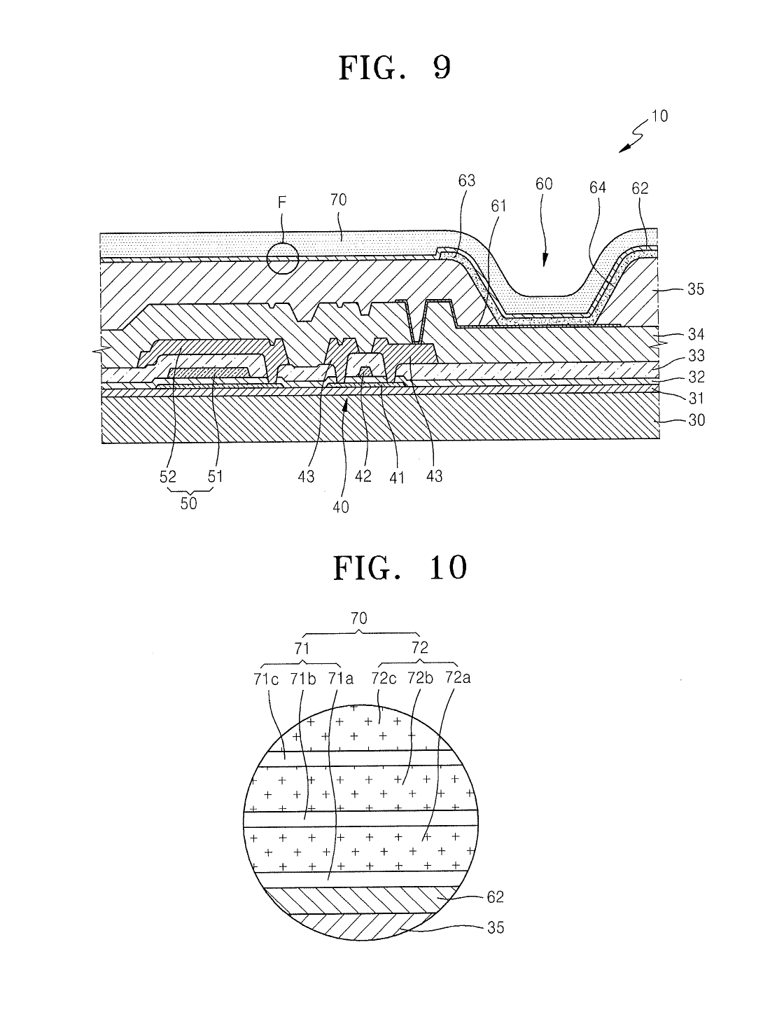

FIG. 9 is a cross-sectional view of an organic light-emitting display apparatus 10 manufactured by an organic light-emitting display apparatus manufacturing method, according to an exemplary embodiment. FIG. 10 is a magnified view of F in FIG. 9.

In more detail, FIGS. 9 and 10 illustrate the organic light-emitting display apparatus 10 manufactured by using one of the vapor deposition apparatuses 100, 200, 300, and 400. For convenience of description, the present embodiment will be described with the vapor deposition apparatus 100.

The organic light-emitting display apparatus 10 is formed on a substrate 30. The substrate 30 may be foamed of a glass material, a plastic material, or a metal material.

A buffer layer 31 containing a conductive material is formed on the substrate 30 so as to provide a flat surface on the substrate 30 and to reduce the possibility of and/or prevent moisture and foreign substances from penetrating into the substrate 30.

A thin film transistor (TFT) 40, a capacitor 50, and an organic light-emitting device 60 are formed on the buffer layer 31. The TFT 40 includes an active layer 41, a gate electrode 42, and source and drain electrodes 43. The organic light-emitting device 60 includes a first electrode 61, a second electrode 62, and an intermediate layer 63.

In more detail, the active layer 41 having a predetermined pattern is formed on a top surface of the buffer layer 31. The active layer 41 may contain an inorganic semiconductor material such as silicon, an organic semiconductor material, or an oxide semiconductor material, and may be formed by injecting a p-type dopant or an n-type dopant into one of the semiconductor materials.

A gate insulating layer 32 is formed on the active layer 41. The gate electrode 42 is formed on the gate insulating layer 32 so as to correspond to the active layer 41. Then, an interlayer insulating layer 33 is formed to cover the gate electrode 42, and the source and drain electrodes 43 are formed on the interlayer insulating layer 33. Here, the source and drain electrodes 43 contact predetermined regions of the active layer 41. A passivation layer 34 is formed to cover the source and drain electrodes 43. A separate insulating layer may be further formed on the passivation layer 34 so as to planarize the TFT 40.

The first electrode 61 is formed on the passivation layer 34. The first electrode 61 is electrically connected to one of the source and drain electrodes 43. Then, a pixel-defining layer (PDL) 35 is formed to cover the first electrode 61. An opening 64 is formed in the PDL 35, and then the intermediate layer 63, including an organic emission layer (organic EML), is formed in a region defined by the opening 64. The second electrode 62 is formed on the intermediate layer 63.

An encapsulation layer 70 is formed on the second electrode 62. The encapsulation layer 70 may contain an organic material or an inorganic material and may have a structure in which the organic material and the inorganic material are alternately stacked.

The encapsulation layer 70 may be formed by using the vapor deposition apparatus 100. That is, when the substrate 30 whereon the second electrode 62 is formed passes under the vapor deposition apparatus 100, a desired layer may be formed.

In particular, the encapsulation layer 70 may include an inorganic layer 71 and an organic layer 72. For example, the inorganic layer 71 includes a plurality of layers 71a, 71b, and 71c, and the organic layer 72 includes a plurality of layers 72a, 72b, and 72c. The plurality of layers 71a, 71b, and 71c of the inorganic layer 71 may be formed by using the vapor deposition apparatus 100. The vapor deposition apparatus 100 according to the one or more embodiments has the first regions 110A and 110B and the second regions 120A and 120B, and performs the deposition procedure while the vapor deposition apparatus 100 moves above the substrate 30, so that it is possible to easily form the plurality of inorganic layers 71a, 71b, and 71c having a desired thickness.

However, embodiments are not limited thereto, e.g., other insulating layers including the buffer layer 31, the gate insulating layer 32, the interlayer insulating layer 33, the passivation layer 34, the PDL 35, and the like of the organic light-emitting display apparatus 10 may be formed by using one of the vapor deposition apparatuses 100, 200, 300, and 400.

Also, various thin films including the active layer 41, the gate electrode 42, the source and drain electrodes 43, the first electrode 61, the intermediate layer 63, the second electrode 62, an the like may be formed by using one of the vapor deposition apparatuses 100, 200, 300, and 400.

As described above, when one of the vapor deposition apparatuses 100, 200, 300, and 400 is used, a characteristic of the deposition layer formed by the organic light-emitting display apparatus 10 is improved, so that an electrical characteristic and an image quality of the organic light-emitting display apparatus 10 may be improved.

By way of summation and review, a vapor deposition method may use one or more gases as raw materials to form a thin film. The vapor deposition method includes chemical vapor deposition (CVD), atomic layer deposition (ALD), and the like.

According to the ALD, after a raw material is injected and purged/pumped, a single layer or a composite layer is adsorbed to a substrate. Then, another raw material is injected and purged/pumped, so that a desired single or composite atomic layer is formed.

Among display apparatuses, an organic light-emitting display apparatus is expected to become a next generation display apparatus due to its wide viewing angles, high contrast, and fast response speeds. The organic light-emitting display apparatus includes an intermediate layer having an organic emission layer (organic EML) between a first electrode and a second electrode that face each other, and also includes one or more various thin films.

However, as the organic light-emitting display apparatus becomes larger and is expected to have high definition, it may be difficult to deposit a large thin film with desired characteristics. Also, there are limitations in increasing the efficiency of a process of forming the large thin film.

In contrast, embodiments relate to a vapor deposition apparatus and a method of manufacturing an organic light-emitting display apparatus, whereby a deposition procedure may be efficiently performed and a characteristic of a deposition layer may be easily improved. That is, according to the vapor deposition apparatus and the method of manufacturing the organic light-emitting display apparatus of the one or more embodiments, the deposition procedure may be efficiently performed and a characteristic of the deposition layer may be easily improved.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A vapor deposition apparatus for depositing a thin film on a substrate, the vapor deposition apparatus comprising:
at least one first region including a first injecting unit that injects a first raw material, a first purging unit that injects a first purge gas, and a first exhausting unit that performs a pumping operation and that is between the first injecting unit and the first purging unit;
at least one second region including a second injecting unit that injects a second raw material, a second purging unit that injects a second purge gas, and a second exhausting unit that performs a pumping operation and that is between the second injecting unit and the second purging unit;
a first blocking unit A arranged between the first exhausting unit and the first injecting unit and between the first exhausting unit and the first purging unit in the at least one first region so as to avoid any common region between the first exhausting unit and the first injecting unit and to avoid any common region between the first exhausting unit and the first purging unit; and
a first blocking unit B arranged between the second exhausting unit and the second injecting unit and between the second exhausting unit and the second purging unit in the at least one second region so as to avoid any common region between the second exhausting unit and the second injecting unit and to avoid any common region between the second exhausting unit and the second purging unit.

2. The vapor deposition apparatus of claim 1, further comprising a second blocking unit A that is adjacent to a side surface of the first injecting unit, which side surface is in an opposite direction with respect to the first exhausting unit and that is between the first injecting unit and a gas injecting unit of another second region adjacent to the first injecting unit, and
wherein the first blocking unit A extends to correspond to at least the second blocking unit A.

3. The vapor deposition apparatus of claim 1, further comprising a second blocking unit A that is adjacent to a side surface of the first injecting unit, which side surface is in an opposite direction with respect to the first exhausting unit and that is between the first injecting unit and a gas injecting unit of another second region adjacent to the first injecting unit, and
wherein a bottom surface of the first blocking unit A and a bottom surface of the second blocking unit A are coplanar with each other.

4. The vapor deposition apparatus of claim 1, further comprising a second blocking unit B that is adjacent to a side surface of the second injecting unit, which side surface is in an opposite direction with respect to the second exhausting unit and that is between the second injecting unit and a gas injecting unit of another first region adjacent to the second injecting unit, and
wherein the first blocking unit B extends to correspond to at least the second blocking unit B.

5. The vapor deposition apparatus of claim 1, further comprising a second blocking unit B that is adjacent to a side surface of the second injecting unit, which side surface is in an opposite direction with respect to the second exhausting unit and that is between the second injecting unit and a gas injecting unit of another first region adjacent to the second injecting unit, and
wherein a bottom surface of the first blocking unit B and a bottom surface of the second blocking unit B are coplanar with each other.

6. The vapor deposition apparatus of claim 1, further comprising a third blocking unit A that is adjacent to a side surface of the first purging unit, which side surface is in an opposite direction with respect to the first exhausting unit and that defines the first purging unit, and
wherein the first blocking unit A extends to correspond to at least the third blocking unit A.

7. The vapor deposition apparatus of claim 1, further comprising a third blocking unit A that is adjacent to a side surface of the first purging unit, which side surface is in an opposite direction with respect to the first exhausting unit and that defines the first purging unit, and
wherein a bottom surface of the first blocking unit A and a bottom surface of the third blocking unit A are coplanar with each other.

8. The vapor deposition apparatus of claim 1, further comprising a third blocking unit B that is adjacent to a side surface of the second purging unit, which side surface is in an opposite direction with respect to the second exhausting unit and that defines the second purging unit, and
wherein the first blocking unit B extends to correspond to at least the third blocking unit B.

9. The vapor deposition apparatus of claim 1, further comprising a third blocking unit B that is adjacent to a side surface of the second purging unit, which side surface is in an opposite direction with respect to the second exhausting unit and that defines the second purging unit, and
wherein a bottom surface of the first blocking unit B and a bottom surface of the third blocking unit B are coplanar with each other.

10. The vapor deposition apparatus of claim 1, further comprising a first curtain unit between a first purging unit of the at least one first region and a second injecting unit of the at least one second region.

11. The vapor deposition apparatus of claim 10, wherein the first purging unit is closer to the first exhausting unit than the first curtain unit.

12. The vapor deposition apparatus of claim 10, wherein a gas pressure applied to the first purging unit is greater than another gas pressure applied to the first curtain unit.

13. The vapor deposition apparatus of claim 10, wherein a width of the first purging unit is less than a width of the first curtain unit.

14. The vapor deposition apparatus of claim 10, wherein a height of the first purging unit is less than a height of the first curtain unit.

15. The vapor deposition apparatus of claim 10, wherein a supply unit for supplying the first purge gas to the first purging unit is connected with another supply unit for supplying a curtain gas to the first curtain unit.

16. The vapor deposition apparatus of claim 1, further comprising a second curtain unit between a second purging unit of the at least one second region and a first injecting unit of the at least one first region.

17. The vapor deposition apparatus of claim 16, wherein the second purging unit is closer to the second exhausting unit than the second curtain unit.

18. The vapor deposition apparatus of claim 16, wherein a gas pressure applied to the second purging unit is greater than another gas pressure applied to the second curtain unit.

19. The vapor deposition apparatus of claim 16, wherein a width of the second purging unit is less than a width of the second curtain unit.

20. The vapor deposition apparatus of claim 16, wherein a height of the second purging unit is less than a height of the second curtain unit.

21. The vapor deposition apparatus of claim 16, wherein a supply unit for supplying the second purge gas to the second purging unit is connected with another supply unit for supplying a curtain gas to the second curtain unit.

22. The vapor deposition apparatus of claim 1, wherein the vapor deposition apparatus deposits a thin film on the substrate while relative movement with respect to the substrate is effected.

23. The vapor deposition apparatus of claim 1, wherein the second raw material is in a radical form and is injected into the substrate.

24. The vapor deposition apparatus of claim 1, wherein a second injecting unit of the at least one second region includes
a plasma generator;
a corresponding surface that corresponds to the plasma generator;
a plasma generation space between the plasma generator and the corresponding surface, the second raw material being formed in the plasma generation space;
a plurality of slits that are arrayed in one direction and that pass the second raw material in a radical form therethrough; and
an injection region via which the second raw material passed through the plurality of slits are injected into the substrate.

25. The vapor deposition apparatus of claim 24, wherein the plurality of slits further have slits that are arrayed in another direction crossing the one direction.

26. The vapor deposition apparatus of claim 25, wherein slits in a center from among the plurality of slits are smaller than slits in a side from among the plurality of slits.

27. The vapor deposition apparatus of claim 24, wherein:
the vapor deposition apparatus includes a plurality of second regions, and
slits arranged in one of the plurality of second regions deviate from slits arranged in another one of the plurality of second regions.

28. The vapor deposition apparatus of claim 24, wherein side surfaces of each of the plurality of slits are curved.

29. The vapor deposition apparatus of claim 24, wherein the plasma generator rotates in one direction.

30. The vapor deposition apparatus of claim 24, wherein:
the vapor deposition apparatus includes a plurality of second regions, and
one plasma generator arranged in one of the plurality of second regions and another plasma generator arranged in another one of the plurality of second regions rotate in different directions.

31. The vapor deposition apparatus of claim 1, wherein:
the vapor deposition apparatus includes a plurality of first regions and a plurality of second regions, and
the plurality of first regions and the plurality of second regions are alternately arranged, respectively.
